(19) United States
(12) Patent Application Publication
(10) Pub. No.: US 2025/0286565 A1
(43) Pub. Date: Sep. 11, 2025

(54) QUASI-CYCLIC LDPC CODES BASED ON GENERALISED QUADRANGLES

(71) Applicant: UNIVERSITAT POLITÈCNICA DE CATALUNYA, Barcelona (ES)

(72) Inventors: Simeon Michael BALL MARKS, Castelldefels (ES); Tomás ORTEGA SÁNCHEZ COLOMER, Sant Cugat Del Vallès (ES)

(21) Appl. No.: 18/863,823

(22) PCT Filed: May 12, 2023
(86) PCT No.: PCT/EP2023/062797

§ 371 Date: Nov. 7, 2024

(30) Foreign Application Priority Data
May 13, 2022 (EP) 22382467.3

(51) Int. Cl. H03M 13/11

(52) U.S. Cl. CPC H03M 13/116; H03M 13/1105

(57) ABSTRACT

In an aspect, digital communication coding methods (or simply coding methods) are provided, said methods comprising providing families of quasi-cyclic low-density parity check, LDPC, codes each represented by a single equation. Said single equation is derived from a geometry whose nature implies good error correcting properties for each of the LDPC codes and allows quasi-cyclic parity check matrices to be constructed for geometric LDPC codes of exceedingly long length, up to and exceeding four hundred thousand bits. The construction of such check matrices is not possible by any other known method. The LDPC codes have different lengths and different rates and the families of LDPC codes are provided with a guarantee of minimum distance. The geometric and quasi-cyclic properties of the LDPC codes allow low complexity decoding with very low frame error rates. Systems, computing systems and computer programs suitable to perform such coding methods are also provided.

### CROSS-REFERENCE TO RELATED APPLICATIONS AND PRIORITY

This patent application claims priority from International Patent Application No. PCT/EP2023/062797 filed May 12, 2023, which claims priority to European Patent Application EP22382467.3 filed May 13, 2022. Each of these patent applications are herein incorporated by reference in its/their entirety.

The present disclosure relates to digital communication coding methods and to systems, computing systems and computing programs suitable for performing such methods.

The present disclosure further relates to methods, systems, computing systems and computing programs to encode and decode data in digital communications.

### BACKGROUND

As known to the person skilled in the art a low-density parity-check (LDPC) code C is a linear code determined by a sparse parity-check matrix H having a small number of 1s per column. The parity-check matrix H may be represented by a bipartite Tanner graph wherein each column of H is represented by a transmitted variable node, each row by a check node, and each “1” in H by a graph edge connecting the variable node and check node that correspond to the column-row location of the “1”. Each check or constraint node defines a parity check operation. The fraction of a transmission that carries information is called the rate of the code. An LDPC code may be encoded by deriving an appropriate generator matrix G from its parity-check matrix H. An LDPC code may be decoded efficiently using well-known iterative decoding algorithms that pass messages along edges of the code's Tanner graph from variable nodes to check nodes and vice-versa until convergence is obtained. However, for very long codes, such iterative processes may by costly and lower complexity algorithms are also well known, which do perform efficiently for certain long LDPC codes in which the column weight is relatively high.

A quasi-cyclic low-density parity-check matrix is completely determined by a reduced matrix Hᵣₑₚ whose (i, j) entry (Hᵣₑₚ)ᵢⱼ consists of either the empty set or a small subset of numbers between zero and b−1, where b is the block size. The low-density parity-check matrix H is recovered from the reduced matrix Hᵣₑₚ by replacing each number r∈(Hᵣₑₚ)ᵢⱼ by the identity matrix of dimension b shifted cyclically r bits to the right and by replacing the empty set by the square zero matrix of dimension b. A quasi-cyclic generator matrix G in standard form may be found for the LDPC code by Gaussian elimination on the blocks. This allows fast encoding of the data bits as explained in [Z. Li, L. Chen, L. Zeng, W. Fong and S. Lin, Efficient encoding of quasi-cyclic low-density parity-check codes, IEEE Trans. Inform. Theory, 54 (2006) 71-81; doi:10.1109/TCOMM.2005.861667].

A finite incidence structure is given by a pair (P, L) where P is a finite set called the set of points and L is the set of lines, which are subsets of P of a fixed size. Classical examples may be obtained by considering P to be a set of r-dimensional subspaces of a finite dimensional vector space V over a finite field F, and L a set of s-dimensional subspaces of V, where s≥r+1. A point x∈P is incident with the line l (i.e., x∈l) if and only if the r-dimensional subspace x is contained in the s-dimensional subspace l. A check matrix for an LDPC code may be made from (P, L) by labelling the rows by elements x of P and the columns by elements l of L. The corresponding entry is zero if x is not in l and 1 if x∈l.

It is known that finite projective, affine and polar spaces may provide check matrices for LDPC codes which are quasi-cyclic. In [Y. Kou, S. Lin and M. P. C. Fossorier, “Low-density parity-check codes based on finite geometries: a rediscovery and new results,” in IEEE Transactions on Information Theory, vol. 47, no. 7, pp. 2711-2736, November 2001, doi: 10.1109/18.959255] the quasi-cyclic structure of finite projective and affine spaces are used to construct efficient LDPC codes of lengths up to approximately 16,000 bits. To construct longer codes however, they use column splitting operations. This results in codes of significantly longer length, up to approximately 500,000 bits, but these codes are not geometric, although they may perform close to Shannon's limit, see Example 4. Meanwhile, in [Zhenyu Liu and D. A. Pados, “LDPC codes from generalized polygons,” in IEEE Transactions on Information Theory, vol. 51, no. 11, pp. 3890-3898, November 2005, doi: 10.1109/TIT.2005.856936.] the block sizes b of the quasi-cyclic matrices for finite generalized polygons is determined. Again, however, there is no method given to actually construct these matrices for codes of arbitrarily long length such as, e.g., above approximately 20000 bits. Thus, there is, until now, no known method to calculate the check matrices of long geometric LDPC codes. Herein, it is described how this may be done by using certain equations which allow the construction of a quasi-cyclic check matrix for such codes.

An object of this disclosure is to provide new methods, systems, computer systems and computer programs aimed at improving currently known digital communication coding methods, systems, computer systems and computer programs.

### SUMMARY

In an aspect, digital communication coding methods (or simply coding methods) are provided, said methods comprising providing families of quasi-cyclic low-density parity-check codes, LDPC codes, each represented by a single equation. Said single equation is derived from a geometry whose nature implies good error correcting properties for each of the LDPC codes and allows quasi-cyclic parity check matrices to be constructed for geometric LDPC codes of exceedingly long length, up to and exceeding four hundred thousand bits. The construction of such check matrices is not possible by any other known method. The LDPC codes have different lengths and different rates and the families of LDPC codes are provided with a guarantee of minimum distance. The geometric and quasi-cyclic properties of the LDPC codes allow low complexity decoding with very low frame error rates.

Digital communication coding methods may further comprise puncturing at least one check bit from one or more of the LDPC codes.

Digital communication encoding methods (or simply encoding methods) are provided. These encoding methods are described in other parts of the disclosure. The encoding is done by adding redundancy bits based on LDPC codes generated by the coding method.

Digital communication decoding methods (or simply decoding methods) are provided. These decoding methods are described in other parts of the disclosure. The decoding is done by correcting errors introduced by potentially noisy communication channel, said correction based on innovative LDPC codes generated or outputted by the coding method.

Methods of producing a digital communication coding hardware (or simply coding hardware) may be provided. Said methods include a coding method such as the ones described in other parts of the disclosure and producing the coding hardware based on innovative LDPC codes generated or outputted by the coding method. Digital communication coding hardwares generated by methods of producing coding hardware may also be provided.

In a further aspect, digital communication coding systems (or simply coding systems) are provided. These systems comprise a system module configured to provide families of quasi-cyclic low-density parity-check, LDPC, codes each represented by a single equation. Such a single equation is derived from a geometry whose nature implies good error correcting properties for each of the LDPC codes and allows quasi-cyclic parity check matrices to be constructed for geometric LDPC codes of exceedingly long length, up to and in excess of four hundred thousand bits. The construction of such check matrices is not possible by any other known method. The LDPC codes have different lengths and different rates, and the families of LDPC codes are provided with a guarantee of minimum distance. The geometric and quasi-cyclic properties of the LDPC codes allow low complexity decoding with very low frame error rates.

Digital communication transmission systems (or simply transmission systems) are disclosed. These transmission systems may include an encoding module and a transmission module. The encoding module may be configured to encode data based on innovative LDPC codes generated by any of the methods, systems, computing systems and computing programs aimed at that, which are described in other parts of the disclosure. The transmission module may be configured to transmit the encoded data through, e.g., a potentially noisy communication channel.

Digital communication receiver systems (or simply receiver systems) are disclosed. These receiver systems may comprise a receiving module and a decoding module. The receiving module may be configured to receive data through, e.g., a potentially noisy communication channel. The decoding module may be configured to decode the received data based on innovative LDPC codes generated by any of the methods, systems, computing systems and computing programs aimed at that, which are described in other parts of the present disclosure.

In a still further aspect, a computer program is provided comprising program instructions for causing a computer or computing system to perform digital communication coding methods such as the ones described in other parts of the disclosure. The computer program may be embodied on a storage medium and/or carried on a carrier signal.

In a furthermore aspect, a computing system is provided for coding data in digital communications, the computing system comprising a memory and a processor, embodying instructions stored in the memory and executable by the processor, and the instructions comprising functionality or functionalities to execute digital communication coding methods, such as the ones described in other parts of the disclosure.

### BRIEF DESCRIPTION OF THE DRAWINGS

Non-limiting examples of the disclosure will be described in the following, with reference to the appended drawings, in which:

FIG. 1 is a block diagram schematically illustrating a digital communication coding system along with systems for producing digital communication coding hardware and software and combination thereof.

FIG. 2 is a block diagram schematically illustrating digital communication transmission system and digital communication receiver system configured to digitally communicate with each other.

FIG. 3 is a flow chart schematically illustrating a digital communication coding method along with methods of producing digital communication coding hardware and software and combination thereof, which are suitable for being performed by systems according to, e.g., FIG. 1.

FIG. 4 is a flow chart schematically illustrating a digital communication encoding method and a digital communication decoding method, which may be used or implemented by digital communication transmitter and receiver systems according to, e.g., FIG. 2.

FIG. 5 is a flow chart schematically illustrating particular manners of generating LDPC codes according to principles described with reference to FIG. 1.

FIG. 6 is a schematic graphic representation of the quasi-cyclic check matrix H and the quasi-cyclic generator matrix G for geometry Q(5,3).

### DETAILED DESCRIPTION

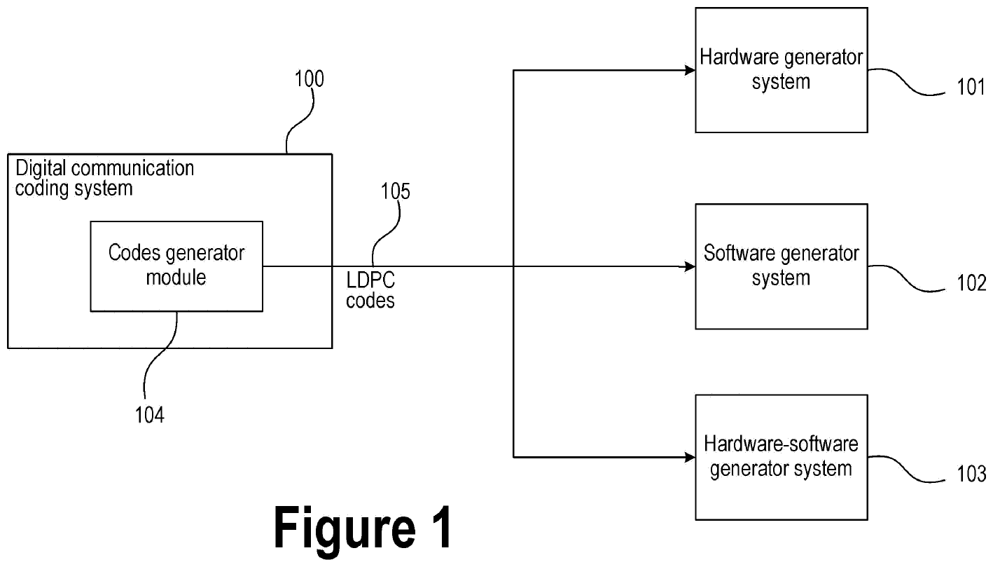

FIG. 1 is a block diagram schematically illustrating a digital communication coding system 100 along with systems for producing digital communication coding hardware 101 or software 102 or combination thereof 103.

As shown in this figure, digital communication coding system 100 outputs LDPC codes 105 which may then be used by system (also denominated hardware generator system) 101 to produce digital communication coding hardware, that may be configured to generate or produce corresponding digital communication coding hardware (e.g., a chip). This output of the hardware generator system 101 may be or include, e.g., a design or specs of a fully hardware-based implementation of data encoder/decoder based on innovative LDPC codes 105 outputted by digital communication coding system 100.

LDPC codes 105 outputted by digital communication coding system 100 may further or alternatively be used by system (also denominated software generator system) 102 to produce digital communication coding software, which may be configured to generate or produce corresponding digital communication coding software (or computer program). This output of the software generator system 102 may be or include a fully software-based implementation of data encoder/decoder based on innovative LDPC codes 105 from digital communication coding system 100.

LDPC codes 105 outputted by digital communication coding system 100 may further or alternatively be used by system (also denominated hardware-software generator system) 103 to produce digital communication coding hardware-software, which may be configured to generate or produce corresponding digital communication coding hardware-software. This output of the hardware-software generator system 103 may be or include an implementation of data encoder/decoder combining hardware and software based on innovative LDPC codes 105 from digital communication coding system 100.

Digital communication coding systems 100 may comprise a module (also denominated codes generator module) 104 configured to provide families of quasi-cyclic low-density parity-check, LDPC codes 105 each of which is represented by a single equation. Said single equation is derived from a geometry whose nature implies good error correcting properties for each of the LDPC codes 105. Moreover, the equations provide a quasi-cyclic check matrix for geometric LDPC codes. The lengths of these codes can be exceedingly long. Construction of such check matrices is not possible by any other known method different from digital communication coding systems 100 according to present disclosure. The LDPC codes 105 have different lengths and different rates and the families of LDPC codes 105 have a guarantee of minimum distance. The geometric and quasi-cyclic properties of the LDPC codes 105 allow the implementation of low complexity decoding with very low frame error rates. Different manners of how module 104 in digital communication coding system 100 may operate to generate corresponding LDPC codes 105 are described in detail below.

A key aspect of module 104 in digital communication coding system 100 is the generation of subsets (H^{rep})ᵢⱼ for geometric LDPC codes 105. These LDPC codes 105 have good error-correcting properties and are efficient to encode and, in turn, may be decoded quickly using low complexity decoding algorithms. The subsets (H^{rep})ᵢⱼ are predetermined by fixing a finite geometry to which an equation is associated. This equation is a low-degree polynomial f(xᵢ, aⱼ) or f(xᵢ, aⱼ, cⱼ), where xᵢ (respectively aⱼ or (aⱼ, cⱼ)) runs through a determined subset of the elements of a finite field F=GF(q^{h}) representing a block of points (respectively lines) of the geometry. The block size b is a divisor of q^{h}−1. Construction of the geometry in this way allows the removal of small substructures of the geometry that greatly increase the size of the blocks b, thereby enhancing the ease of implementation of the LDPC codes 105.

The LDPC codes 105 may therefore be described by their parity check matrix which may be constructed from the equation, where q may be chosen so that the LDPC code 105 has the desired rate and length. Once q and the geometry have been chosen, the block size b is given in following Table 1, as are the index sets of rows and columns of H^{rep}. The rows are indexed by x₀ and the columns by a₀ (in the projective, elliptic and symplectic case) and (a₀, c) (in the hermitian case), which satisfy the equation given in the final column of following Table 1. Except for the projective case, for each x₀ and a₀ satisfying the defining conditions, xᵢ, aⱼ∈F are found such that xᵢ^{b}=x₀ and aⱼ^{b}=a₀. In the projective case, xᵢ, aⱼ∈F are found such that xᵢ^{b}=x₀ and aⱼ^{q}^{²}⁺¹=a₀.

TABLE 1

| | block | dimension | finite | defining equation | condition |
|---|---|---|---|---|---|
| Geometry | size b | H^{rep} | field F | f(x, a) or f(x, a, c) | on x₀ and a₀ |
| PG(3, q) | (q + 1)(q² + 1) | 1 × q | GF(q [symbol] ) | γax^{q+1} + x + a [symbol] | 1 − x₀ = 0 |
| projective | | | | | γ fixed such that γ^{q+1} = −1 |
| | | | | | (γa₀)^{q} + γa₀ − 1 = 0 |
| | | | | | x₀ = x^{b}, a₀ = a [symbol] |
| W(3, q) | q² + 1 | (q +1) × q | GF(q [symbol] ) | ax^{q+1} + x − γ [symbol] | 1 − [symbol] = 0 |
| symplecfic | | | | | 1 − [symbol] = 0 |
| [symbol] | | | | | γ fixed such that [symbol] = −γ |
| | | | | | x₀ = x^{b}, a₀ = a^{b} |
| Q(5, q) | q³ + 1 | (q + 1) × q² | GF(q [symbol] ) | ax^{q+1} − x + a [symbol] | 1 + x₀ + [symbol] = 0 |
| elliptic | | | | | 1 + a₀ + [symbol] + [symbol] = 0 |
| [symbol] | | | | | x₀ = x^{b}, a₀ = a^{b} |
| H(4, q²) hermitian [symbol] | $\frac{\text{?} + \text{?}}{\text{?} + \text{?}}$ | (q + 1)(q² + 1) × (q + 1)(q³ + 1) | GF(q [symbol] ) | [symbol] | 1 + [symbol] = 0 condition (2) below x₀ = x^{b}, a₀ = a^{b} |

The block size, dimension of H^{rep}, finite field and the defining equation. The rows of H^{rep} are indexed by x₀ and the columns of H^{rep} are indexed by a₀ (or (a₀, c)). [symbol]
indicates data missing or illegible when filed

The conditions on a₀ and c for H(4, q²) are given by (c, a₀)∈L₁∪L₂, where:

$${L}_{1} \{ ( c , {a}_{0} ) \vert {F}_{1} ( c ) \neq 0 , {F}_{2} ( c ) = 0 , {a}_{0} = \frac{c ( {c}^{{q}^{2} + {q}^{4}} + {c}^{{q}^{2}} - {c}^{{q}^{4} + {q}^{3} - q} - {c}^{{q}^{4} + {q}^{2}} )}{( {c}^{{q}^{4} + q} + {c}^{4} + {c}^{{q}^{4} + {q}^{3} + q} + {c}^{q + {q}^{3}} + {c}^{{q}^{3} + {q}^{4}} )} \} \qquad ( 2 )$$

$$and$$

$${F}_{1} ( c ) = {( 1 + c )}^{{q}^{2} + 1} + {c}^{q} , and {F}_{2} ( c ) = {( 1 + c )}^{{q}^{4} + 1} + {c}^{{q}^{4} - {q}^{2} + 1} .$$

The subset (H^{rep})ᵢⱼ is then determined by the defining equation in following way.

Let ∝ be a primitive b-th root of unity in the finite field F with q^{h} elements.

If the defining equation is f(xᵢ, aⱼ) (respectively f(xᵢ, aⱼ, cⱼ)) then the condition is r∈(H^{rep})ᵢⱼ if and only if

$$f ( {α}^{r} {x}_{i} , {α}_{j} ) = 0 , ( resp . f ( {α}^{r} {x}_{i} , {α}_{j} . {c}_{j} ) = 0 ) \qquad ( 1 )$$

where r runs from 0 to b−1.

The reduced parity check matrix H^{rep} for the dual of these codes is constructed by the rule

$$\begin{matrix}{( \overline{{H}^{rep}} )}_{ij} = \{ - r & ( mod b ) \vert\end{matrix} r ∈ {( {H}^{rep} )}_{ji} \} .$$

The length of the code, a lower bound on minimum distance, transmission rate and complexity of constructing H^{rep} are given in following Table 2.

TABLE 2

| | block | length | column | row | complex - | complex - | min. | approx. |
|---|---|---|---|---|---|---|---|---|
| Code | size b | n | weight | weight | [symbol] | [symbol] | dist. | rate |
| PG(3, q) | (q + 1)(q³ + 1) | qb | q + 1 | q(q + 1) | O(q⁴) | O(q [symbol] ) | ≥q + 2 | 1 − q⁻¹ |
| W(3, q) | q² + 1 | qb | q + 1 | q | O(q⁴) | O(q [symbol] ) | ≥2q | 1 − q [symbol] (q even) |
| | | | | | | | | 0.5(q odd) |
| W(3, q) | q² + 1 | (q + 1)b | q | q + 1 | O(q⁴) | O(q [symbol] ) | ≥2q | 1 − q [symbol] (q even) |
| dual | | | | | | | | 0.5(q odd) |
| Q(5, q) | q³ + 1 | q²b | q + 1 | q² | O(q⁶) | O(q [symbol] ) | ≥2q | 1 − q⁻¹ |
| Q(5, q) | q³ + 1 | (q + 1)b | q² | q | O(q⁶) | O(q [symbol] ) | ≥2q³ | q⁻¹ |
| dual | | | | | | | | |
| H(4, q²) | $\frac{\text{?} + \text{?}}{\text{?} + \text{?}}$ | (q + 1)(q³ + 1)b | q² + 1 | q³ + 1 | O(q [symbol] ) | O(q [symbol] ) | ≥2q [symbol] | 1 − q⁻¹ |
| H(4, q²) dual | $\frac{\text{?} + \text{?}}{\text{?} + \text{?}}$ | (q + 1)(q² + 1)b | q³ + 1 | q² + 1 | O(q [symbol] ) | O(q [symbol] ) | ≥q [symbol] | q⁻¹ |

Block size, length, and complexity of constructing H^{rep} and P^{rep}. [symbol]
indicates data missing or illegible when filed

As mentioned above a quasi-cyclic generator matrix for the LDPC code 105 may be obtained efficiently by performing Gaussian elimination on the blocks of H^{rep}, to obtain a quasi-cyclic parity check matrix in standard form (which may not be low-density) and then transposing the part of the matrix corresponding to the check bits in the standard way. The quasi-cyclic generator matrix may be described by a reduced generator matrix P^{rep} which consists of the first row of each block matrix making up the blocks of the check bit part of the generator matrix. The matrix P^{rep} may be constructed as described in [Z. Li, L. Chen, L. Zeng, W. Fong and S. Lin, “Efficient encoding of quasi-cyclic low-density parity-check codes”, IEEE Trans. Inform. Theory, 54 (2006) 71-81; doi:10.1109/TCOMM.2005.861667], where examples of circuits are given which implement encodings using such quasi-cyclic generator matrices. The complexity of constructing P^{rep} is given in previous Table 2.

A real-time field programmable gate array (FPGA) decoder was used to implement the LDPC code 105 from Q(5, 13) of length 371462. The performance of this code, as well as computer simulations for shorter length code derived from Q(5, q) (see following Table 3) consistently perform within 1-1.5 dB's of Shannon's limit. Importantly, the LDPC codes 105 have no visible error floor. Another important advantage of using these geometric LDPC codes 105 is that low complexity decoding algorithms may be implemented which perform almost as well as slower sum-product decoding algorithms which require many iterations to converge. Such low complexity decoding algorithms are described in [Y. Kou, S. Lin and M. P. C. Fossorier, “Low-density parity-check codes based on finite geometries: a rediscovery and new results,” in IEEE Transactions on Information Theory, vol. 47, no. 7, pp. 2711-2736, November 2001, doi: 10.1109/18.959255]. These algorithms work well partly because of a relatively high column weight. The column weights and row weights of H are detailed in previous Table 2.

TABLE 3
Elliptic quadric quadrangle Q(5, q).

| q | length [symbol] | block size b | H^{rep} | rank H | dim C | rate C | dim C [symbol] | rate C [symbol] | P^{rep} |
|---|---|---|---|---|---|---|---|---|---|
| 3 | 252 | 28 | 4 × 9 | 91 | 161 | 0.63889 | 140 | 0.55555 | 5 × 4 |
| 4 | 1040 | 65 | 5 × 16 | 261 | 779 | 0.74904 | 715 | 0.6875 | 11 × 5 |
| 5 | 3150 | 126 | 6 × 25 | 651 | 2499 | 0.79333 | 2394 | 0.76 | 19 × 6 |
| 7 | 16856 | 344 | 8 × 49 | 2451 | 14405 | 0.85459 | 14104 | 0.83673 | 41 × 8 |
| 8 | 32832 | 513 | 9 × 64 | 3681 | 29151 | 0.88788 | 28215 | 0.85938 | 55 × 9 |
| 9 | 59130 | 730 | 10 × 81 | 6643 | 52487 | 0.88766 | 51830 | 0.87654 | 71 × 10 |
| 11 | 161172 | 1332 | 12 × 121 | 14763 | 146409 | 0.90840 | 145188 | 0.90083 | 109 × 12 |
| 13 | 371462 | 2198 | 14 × 169 | 28731 | 342731 | 0.92265 | 340690 | 0.91716 | 155 × 14 |

[symbol]

indicates data missing or illegible when filed

LDPC codes 105 constructed from the point-line incidence matrices of generalised quadrangles have the property that Tanner graph of the check matrix has no cycles of length less than 8. In the case of projective and affine geometries, Tanner graph of the check matrix have no cycles of length less than 6. This, along with bounds on the minimum distance given in previous Table 2, imply good error-correcting properties.

The parameters of the LDPC codes 105 for various values of q are given in previous Table 3 and following Tables 4, 5, 6, 7 and 8. It is not necessarily the case that a quasi-cyclic generator matrix in standard form exists for all codes C, so the tables include a code C′ which is the largest subcode of C for which a quasi-cyclic generator matrix in standard form has been calculated.

TABLE 4
Dual elliptic quadric quadrangle Q(5, q).

| q | length [symbol] | block size b | H^{rep} | rank H | dim C | rate C | dim C [symbol] | rate C [symbol] | G^{rep}(†) |
|---|---|---|---|---|---|---|---|---|---|
| 3 | 112 | 28 | 9 × 4 | 91 | 21 | 0.1875 | 21 | 0.1875 | 1 × 4 |
| 5 | 756 | 126 | 25 × 6 | 651 | 105 | 0.13889 | 105 | 0.13889 | 1 × 6 |
| 7 | 2752 | 344 | 49 × 8 | 2451 | 301 | 0.10938 | 301 | 0.10938 | 1 × 8 |
| 9 | 7300 | 730 | 81 × 10 | 6643 | 657 | 0.09 | 657 | 0.09 | 1 × 10 |
| 13 | 30772 | 2198 | 169 × 14 | 28731 | 2041 | 0.0663 | 2041 | 0.0663 | 1 × 14 |

(†)Since the dimension of C is less than the block size a non-standard quasi cyclic generator matrix G^{rep} may be obtained. [symbol]
indicates data missing or illegible when filed

TABLE 5
Symplectic quadrangle W(3, q).

| q | length [symbol] | block size b | H^{rep} | rank H | dim C | rate C | dim C [symbol] | rate C [symbol] | P^{rep} |
|---|---|---|---|---|---|---|---|---|---|
| 5 | 130 | 26 | 6 × 5 | 91 | 39 | 0.3 | 26 | 0.2 | 1 × 4 |
| 7 | 350 | 50 | 8 × 7 | 225 | 125 | 0.35714 | 100 | 0.28571 | 2 × 5 |
| 8 | 520 | 65 | 9 × 8 | 297 | 223 | 0.42885 | 195 | 0.375 | 3 × 5 |
| 9 | 738 | 82 | 10 × 9 | 451 | 287 | 0.38889 | 246 | 0.33333 | 3 × 6 |
| 11 | 1342 | 122 | 12 × 11 | 793 | 549 | 0.40909 | 488 | 0.36364 | 4 × 7 |
| 13 | 2210 | 170 | 14 × 13 | 1275 | 935 | 0.42308 | 680 | 0.30770 | 4 × 9 |
| 16 | 4412 | 257 | 17 × 16 | 1889 | 2223 | 0.54061 | 1799 | 0.4375 | 7 × 9 |
| 17 | 4930 | 290 | 18 × 17 | 2755 | 2175 | 0.44118 | 2030 | 0.41177 | 7 × 10 |
| 19 | 6878 | 362 | 20 × 19 | 3801 | 3077 | 0.44737 | 2896 | 0.42105 | 8 × 11 |
| 23 | 12190 | 530 | 24 × 23 | 6625 | 5565 | 0.45652 | 5300 | 0.43478 | 10 × 13 |
| 25 | 15650 | 636 | 26 × 25 | 8451 | 7199 | 0.46 | 6886 | 0.44 | 11 × 14 |
| 27 | 19710 | 730 | 28 × 27 | 10585 | 9125 | 0.46296 | 8030 | 0.40741 | 11 × 16 |
| 29 | 24418 | 842 | 30 × 29 | 13051 | 11367 | 0.46552 | 10104 | 0.41379 | 12 × 17 |
| 31 | 29822 | 962 | 32 × 31 | 15873 | 13949 | 0.46774 | 13468 | 0.45161 | 14 × 17 |
| 32 | 32800 | 1025 | 33 × 32 | 12249 | 20551 | 0.62655 | 15375 | 0.46875 | 15 × 17 |
| 37 | 50690 | 1370 | 38 × 37 | 26715 | 23975 | 0.47297 | 21920 | 0.43243 | 16 × 21 |
| 41 | 68962 | 1682 | 42 × 41 | 36163 | 32799 | 0.52439 | 31958 | 0.46341 | 19 × 22 |

[symbol]

indicates data missing or illegible when filed

TABLE 6
Dual symplectic quadrangle W(3, q).

| q | length [symbol] | block size b | H^{rep} | rank H | dim C | rate C | dim C [symbol] | rate C [symbol] | P^{rep} |
|---|---|---|---|---|---|---|---|---|---|
| 4 | 85 | 17 | 4 × 5 | 49 | 36 | 0.42353 | 17 | 0.2 | 1 × 4 |
| 5 | 156 | 26 | 5 × 6 | 91 | 65 | 0.41667 | 52 | 0.33333 | 2 × 4 |
| 7 | 400 | 50 | 7 × 8 | 225 | 175 | 0.4375 | 150 | 0.375 | 3 × 5 |
| 8 | 585 | 65 | 8 × 9 | 297 | 288 | 0.49231 | 260 | 0.44444 | 4 × 5 |
| 9 | 820 | 82 | 9 × 10 | 451 | 369 | 0.45 | 328 | 0.4 | 4 × 6 |
| 11 | 1464 | 122 | 11 × 12 | 793 | 671 | 0.45833 | 610 | 0.41667 | 5 × 7 |
| 16 | 4369 | 257 | 16 × 17 | 1889 | 2480 | 0.56764 | 2056 | 0.47059 | 8 × 9 |
| 17 | 5220 | 290 | 17 × 18 | 2755 | 2465 | 0.47222 | 2320 | 0.44444 | 8 × 10 |
| 19 | 7240 | 362 | 19 × 20 | 3801 | 3439 | 0.475 | 3258 | 0.45 | 9 × 11 |
| 23 | 12720 | 530 | 23 × 24 | 6625 | 6095 | 0.47917 | 5830 | 0.45833 | 11 × 13 |
| 25 | 16276 | 626 | 25 × 26 | 8451 | 7825 | 0.48077 | 7512 | 0.46154 | 12 × 14 |
| 27 | 20440 | 730 | 27 × 28 | 10585 | 9855 | 0.48214 | 9490 | 0.46429 | 13 × 15 |
| 29 | 25260 | 842 | 29 × 30 | 13051 | 12209 | 0.48333 | 11788 | 0.46667 | 14 × 16 |
| 31 | 30784 | 962 | 31 × 32 | 15873 | 14911 | 0.48438 | 14430 | 0.46875 | 15 × 17 |
| 32 | 33825 | 1025 | 32 × 33 | 12249 | 21576 | 0.63787 | 16400 | 0.48485 | 16 × 17 |
| 41 | 70664 | 1682 | 41 × 42 | 36163 | 34481 | 0.51176 | 33640 | 0.47619 | 20 × 22 |

[symbol]

indicates data missing or illegible when filed

TABLE 7
Hermitian quadrangle H(4, q²).

| q² | length [symbol] | block size b | H^{rep} | rank H | dim C | rate C | dim C [symbol] | rate C [symbol] | P^{rep} |
|---|---|---|---|---|---|---|---|---|---|
| 4 | 297 | 11 | 15 × 27 | 120 | 177 | 0.59596 | 176 | 0.59259 | 16 × 11 |
| 9 | 6832 | 61 | 40 × 112 | 1891 | 4941 | 0.72321 | 4941 | 0.72321 | 81 × 31 |
| 16 | 66625 | 205 | 85 × 325 | 11050 | 55575 | 0.83415 | 55350 | 0.83077 | 270 × 5 [symbol] |
| 25 | 393876 | 521 | 156 × 756 | 68251 | 325625 | 0.82672 | 325625 | 0.82672 | 625 × 131 |

[symbol]

indicates data missing or illegible when filed

TABLE 8
Dual Hermitian quadrangle H(4, q²).

| q² | length [symbol] | block size b | H^{rep} | rank H | dim C | rate C | dim C [symbol] | rate C [symbol] | P^{rep} |
|---|---|---|---|---|---|---|---|---|---|
| 4 | 165 | 11 | 27 × 15 | 120 | 45 | 0.27273 | 44 | 0.26667 | 4 × 11 |
| 9 | 2440 | 61 | 112 × 40 | 1891 | 549 | 0.225 | 549 | 0.225 | 9 × 31 |
| 16 | 17425 | 205 | 325 × 85 | 11050 | 6375 | 0.36585 | 6150 | 0.35294 | 30 × 5 [symbol] |
| 25 | 81276 | 521 | 756 × 150 | 68251 | 13025 | 0.16026 | 13025 | 0.16026 | 25 × 31 |

[symbol]

indicates data missing or illegible when filed

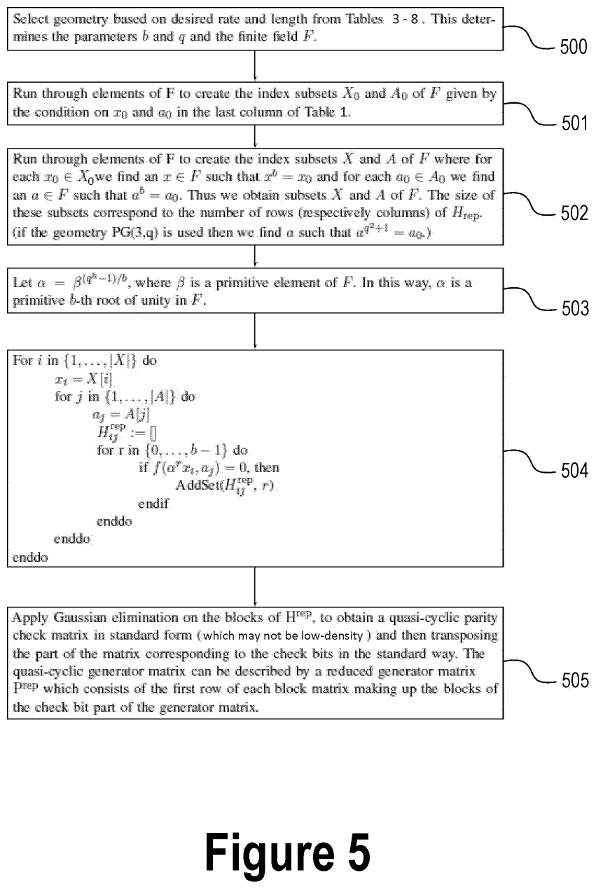

Particular manners of generating LDPC codes based on above principles described regarding FIG. 1 will be described later with reference to FIG. 5.

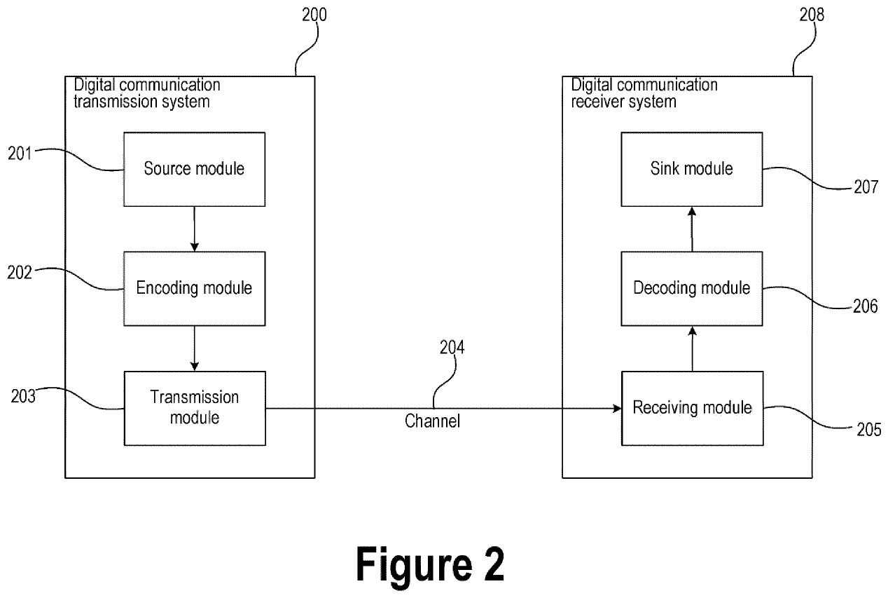

FIG. 2 is a block diagram schematically illustrating digital communication transmission system 200 and digital communication receiver system 208 configured to digitally communicate with each other. As shown in this figure, transmission system 200 and receiver system 208 may communicate with each other through corresponding channel 204 which may (usually) add noise to the transmission.

Transmission systems 200 may include an encoding module (or data encoder) 202 and a transmission module 203. Data encoder 202 may be configured to encode data based on innovative LDPC codes 105 generated by digital communication coding systems 100 according to the present disclosure, such as the ones described with respect to FIG. 1. Data encoder 202 may use (or include or implement) any of the methods, systems, computing systems, software, hardware and software-hardware combinations described herein that are configured to encode data (to be transmitted) based on the LDPC codes 105. Transmission module 203 may include, e.g., a modulator configured to modulate encoded data (outputted by encoding module 202) according to, e.g., specs of the channel 204 through which said encoded data is to be transmitted. Transmission systems 200 may further include, as shown in the figure, a source module 201 which may be configured to generate the data to be transmitted, pre-process preexisting data (to be transmitted) prior to its encoding (at data encoder 202), etc.

Receiver systems 208 may include a receiving module 205 and a decoding module (or data decoder) 206. Receiving module 205 may include, e.g., a demodulator configured to demodulate encoded data received through channel 204 according to, e.g., specs of the channel 204. Data decoder 206 may be configured to decode the received data (optionally once demodulated by receiving module 205) by correcting errors introduced by the (potentially) noisy communication channel 204, based on the innovative LDPC codes 105 generated by digital communication coding systems 100 according to the present disclosure, such as the ones described with respect to FIG. 1. Data decoder 206 may use (or include or implement) any of the methods, systems, computing systems, software, hardware and software-hardware combinations described herein that are configured to decode data (received through channel 204) based on the LDPC codes 105. Receiver systems 208 may further include, as shown in the figure, a sink module 207 which may correspond to a destination unit where decoded data is to be processed according to intended application.

As used herein, the term “module” or “unit” may be understood to refer to software, firmware, hardware and/or various combinations thereof. It is noted that the modules are exemplary. The modules may be combined, integrated, separated, and/or duplicated to support various applications. Also, a function described herein as being performed by a particular module may be performed by one or more other modules and/or by one or more other devices instead of or in addition to the function performed by the described particular module.

The modules may be implemented across multiple devices, associated or linked to corresponding digital communication coding systems proposed herein, and/or to other components that may be local or remote to one another. Additionally, the modules may be moved from one device and added to another device, and/or may be included in both devices, associated to corresponding digital communication coding systems proposed herein. Any software implementations may be tangibly embodied in one or more storage media, such as, e.g., a memory device, a floppy disk, a compact disk (CD), a digital versatile disk (DVD), or other devices that may store computer code or computer instructions.

The digital communication coding systems according to present disclosure may be implemented by computing means, electronic means or a combination thereof. The computing means may be a set of instructions (e.g., a computer program or software) and then digital communication coding systems may comprise a memory and a processor, embodying said set of instructions stored in the memory and executable by the processor. These instructions may comprise functionality or functionalities to execute corresponding digital communication coding methods such as, e.g., the ones described with reference to other figures.

In case the digital communication coding systems are implemented only by electronic means, a controller of the system may be, for example, a CPLD (Complex Programmable Logic Device), an FPGA (Field Programmable Gate Array) or an ASIC (Application-Specific Integrated Circuit).

In case the digital communication coding systems are a combination of electronic and computing means, the computing means may be a set of instructions (e.g., a computer program or software) and the electronic means may be any electronic circuit capable of implementing corresponding digital communication coding methods proposed herein, such as the ones described with reference to other figures.

The computer program(s) may be embodied on a storage medium (for example, a CD-ROM, a DVD, a USB drive, a computer memory or a read-only memory) or carried on a carrier signal (for example, on an electrical or optical carrier signal).

The computer program(s) may be in the form of source code, object code, a code intermediate source and object code such as in partially compiled form, or in any other form suitable for use in implementing digital communication coding methods according to present disclosure. The carrier may be any entity or device capable of carrying the computer program(s).

For example, the carrier may comprise a storage medium, such as a ROM, for example a CD ROM or a semiconductor ROM, or a magnetic recording medium, for example a hard disk. Further, the carrier may be a transmissible carrier such as an electrical or optical signal, which may be conveyed via electrical or optical cable or by radio or other means.

When the computer program(s) is/are embodied in a signal that may be conveyed directly by a cable or other device or means, the carrier may be constituted by such cable or other device or means. Alternatively, the carrier may be an integrated circuit in which the computer program(s) is/are embedded, the integrated circuit being adapted for performing, or for use in the performance of, digital communication coding methods proposed herein.

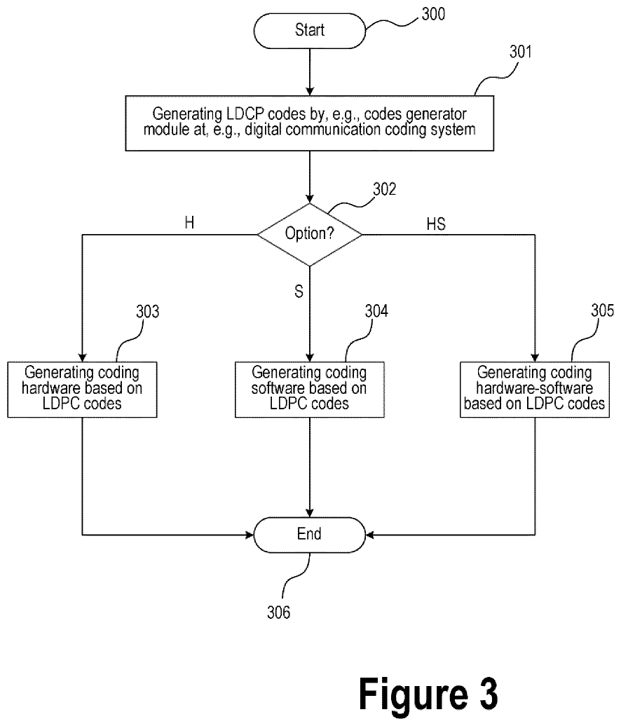

FIG. 3 is a flow chart schematically illustrating a digital communication coding method (or simply coding method) along with methods of producing digital communication coding hardware (or simply hardware producer) and software (or simply software producer) and combination thereof (or simply hardware-software producer), which are suitable for being performed by systems according to, e.g., FIG. 1. Therefore, number references from FIG. 1 may be reused in following description of FIG. 3.

FIG. 3 thus refers to both coding methods (performed by, e.g., digital communication coding systems 100) and producer methods (performed by, e.g., digital communication coding systems 100 in cooperation with hardware generators 101 and/or software generators 102 and/or hardware-software generators 103). Full methods according to FIG. 3 may also be denominated coding and producing methods herein.

As shown in the figure, coding and producing methods may be initiated (e.g., at block 300) upon detection of a starting condition such as, e.g., a user request to start the coding and producing method.

Coding and producing methods may further include (e.g., at method block 301) generating LDPC codes 105 in any of the innovative manners described in other parts of the disclosure. This functionality implemented or implementable by method block 301 may be performed by, e.g., codes generator module 104 (in, e.g., digital communication coding system 100) described with reference to FIG. 1. Functional details and considerations explained about said codes generator module 104 (in, e.g., digital communication coding system 100) may thus be similarly attributed or attributable to method block 301.

Coding and producing methods may further include (e.g., at method block 302) verifying whether hardware (option H) or software (option S) or hardware-software (option HS) or any combination thereof (option H and/or option S and/or option HS) has or have been selected. Such an option or options (H and/or S and/or HS and/or any combination thereof) may have been provided by competent user or operator. In case of option H, transition to method block 303 may be performed. Additionally or alternatively, in case of option S, transition to method block 304 may be performed. Additionally or alternatively, in case of option HS, transition to method block 305 may be performed.

Coding and producing methods may further include (e.g., at method block 303) generating coding hardware based on innovative LDPC codes 105 (from, e.g., method block 301). This functionality implemented or implementable by method block 303 may be performed by, e.g., hardware generator system 101 described with reference to FIG. 1. Functional details and considerations explained about said hardware generator system 101 may thus be similarly attributed or attributable to method block 303.

Coding and producing methods may further include (e.g., at method block 304) generating coding software based on innovative LDPC codes 105 (from, e.g., method block 301). This functionality implemented or implementable by method block 304 may be performed by, e.g., software generator system 102 described with reference to FIG. 1. Functional details and considerations explained about said software generator system 102 may thus be similarly attributed or attributable to method block 304.

Coding and producing methods may further include (e.g., at method block 305) generating coding hardware-software based on innovative LDPC codes 105 (from, e.g., method block 301). This functionality implemented or implementable by method block 305 may be performed by, e.g., hardware-software generator system 103 described with reference to FIG. 1. Functional details and considerations explained about said hardware-software generator system 103 may thus be similarly attributed or attributable to method block 305.

Coding and producing methods may further include (e.g., at method block 306) ending execution of the method upon satisfaction of an ending condition. Such an ending condition may be satisfied when, e.g., hardware generation has been completed (at, e.g., block 303), and/or software generation has been completed (at, e.g., block 304), and/or hardware-software generation has been completed (at, e.g., block 305), and/or user request has been detected requesting termination of the method, etc.

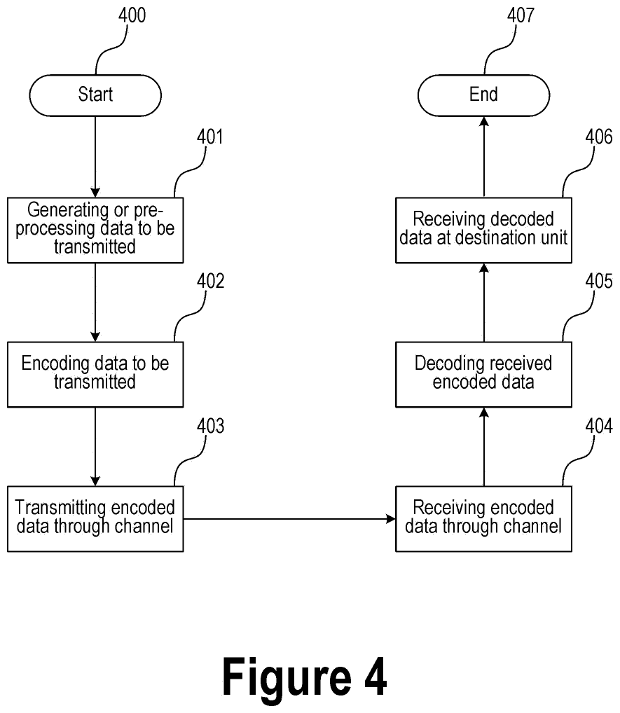

FIG. 4 is a flow chart schematically illustrating a digital communication encoding method (or simply encoding method) and a digital communication decoding method (or simply decoding method), according to examples, which may be used or implemented by digital communication transmitter and receiver systems according to, e.g., FIG. 2. Therefore, number references from FIG. 2 may be reused in following description of FIG. 4. In particular, encoding method 402 may be performed by encoding module 202, decoding method 405 may be performed by decoding module 206, transmission method 401-403 may be performed by transmission system 200, and receiving method 404-406 may be performed by receiver system 208. Full methods exemplary illustrated by FIG. 4 may be denominated transmitting and receiving methods. As shown in the figure, transmitting and receiving methods may be initiated (e.g., at block 400) upon detection of a starting condition such as, e.g., a user request to start the transmitting (and receiving) method.

Transmitting and receiving methods may further include (e.g., at method block 401) generating or pre-processing data to be transmitted. Block 401 may process the data in any manner that prepares the data to be encodable at block 402 and subsequently transmittable at block 403. Block 401 is not necessary if the pre-existing data does not need processing prior to its encoding at block 402. This functionality implemented or implementable by method block 401 may be performed by, e.g., source module 201 (in, e.g., digital communication transmission system 200) described with reference to FIG. 2. Functional details and considerations explained about said source module 201 (in, e.g., digital communication transmission system 200) may thus be similarly attributed or attributable to method block 401.

Transmitting and receiving methods may further include (e.g., at method block 402) encoding the data to be transmitted based on innovative LDPC codes 105. This functionality implemented or implementable by method block 402 may be performed by, e.g., encoding module 202 (in, e.g., digital communication transmission system 200) described with reference to FIG. 2. Functional details and considerations explained about said encoding module 202 (in, e.g., digital communication transmission system 200) may thus be similarly attributed or attributable to method block 402.

Transmitting and receiving methods may further include (e.g., at method block 403) transmitting the encoded data through potentially noisy channel 204. This functionality implemented or implementable by method block 403 may be performed by, e.g., transmission module 203 (in, e.g., digital communication transmission system 200) described with reference to FIG. 2. Functional details and considerations explained about said transmission module 203 (in, e.g., digital communication transmission system 200) may thus be similarly attributed or attributable to method block 403.

Transmitting and receiving methods may further include (e.g., at method block 404) receiving the encoded data (from transmission system 200) through a potentially noisy channel 204. This functionality implemented or implementable by method block 404 may be performed by, e.g., receiving module 205 (in, e.g., digital communication receiver system 208) described with reference to FIG. 2. Functional details and considerations explained about said receiving module 205 (in, e.g., digital communication receiver system 208) may thus be similarly attributed or attributable to method block 404.

Transmitting and receiving methods may further include (e.g., at method block 405) decoding the received data based on innovative LDPC codes 105. This functionality implemented or implementable by method block 405 may be performed by, e.g., decoding module 206 (in, e.g., digital communication receiver system 208) described with reference to FIG. 2. Functional details and considerations explained about said decoding module 206 (in, e.g., digital communication receiver system 208) may thus be similarly attributed or attributable to method block 405.

Transmitting and receiving methods may further include (e.g., at method block 406) receiving decoded data at destination unit (in, e.g., receiver system 208). This functionality implemented or implementable by method block 406 may be performed by, e.g., sink module 207 (in, e.g., digital communication receiver system 208) described with reference to FIG. 2. Functional details and considerations explained about said sink module 207 (in, e.g., digital communication receiver system 208) may thus be similarly attributed or attributable to method block 406.

Transmitting and receiving methods may further include (e.g., at method block 407) ending execution of the method upon satisfaction of an ending condition. Such an ending condition may be satisfied when, e.g., decoded data has been received at destination unit, and/or user request has been detected requesting termination of the method, etc.

FIG. 5 is a flow chart schematically illustrating particular manners of generating LDPC codes according to principles described with reference to FIG. 1. At method block 500, a suitable geometry is selected based on desired rate and length from Tables 3-8. This determines the parameters b and q and the finite field F.

Method block 501 involves running through elements of F to create the index subsets X₀ and A₀ of F given by the condition on x₀ and a₀ in the last column of Table 1.

Method block 502 involves running through elements of F to create the index subsets X and A of F where for each x₀∈X₀ an x∈F is found such that x^{b}=x₀ and for each a₀∈A₀ an a∈F is found such that a^{b}=a₀. Thus, subsets X and A of F are obtained. The size of these subsets corresponds to the number of rows (respectively columns) of H^{rep}. (if the geometry PG(3,q) is used then a is found such that a^{q}^{²}⁺¹=a₀.)

Method block 503 is the following definition: Let α=β^{(q}^{^{h}}^{-1)/b}, where β is a primitive element of F. In this way, α is a primitive b-th root of unity in F.

Method block 504 involves the following calculation:

```
For i in {1,...,|X|} do
  xᵢ = X[i]
  for j in {1,....,|A|} do [symbol]
    = A[j]
      Hᵢⱼ^{rep} := [ ]
      for r in {0,..., b − 1} do
        if f ( [symbol] xᵢ, aⱼ) = 0, then
          AddSet(Hᵢⱼ^{rep}, r)
        endif
      enddo
  enddo
enddo [symbol]
indicates data missing or illegible when filed
```

Method block 505 may include applying Gaussian elimination on the blocks of H^{rep}, to obtain a quasi-cyclic parity check matrix in standard form (which may not be low-density) and then transposing the part of the matrix corresponding to the check bits in the standard way. The quasi-cyclic generator matrix can be described by a reduced generator matrix P^{rep} which consists of the first row of each block matrix making up the blocks of the check bit part of the generator matrix.

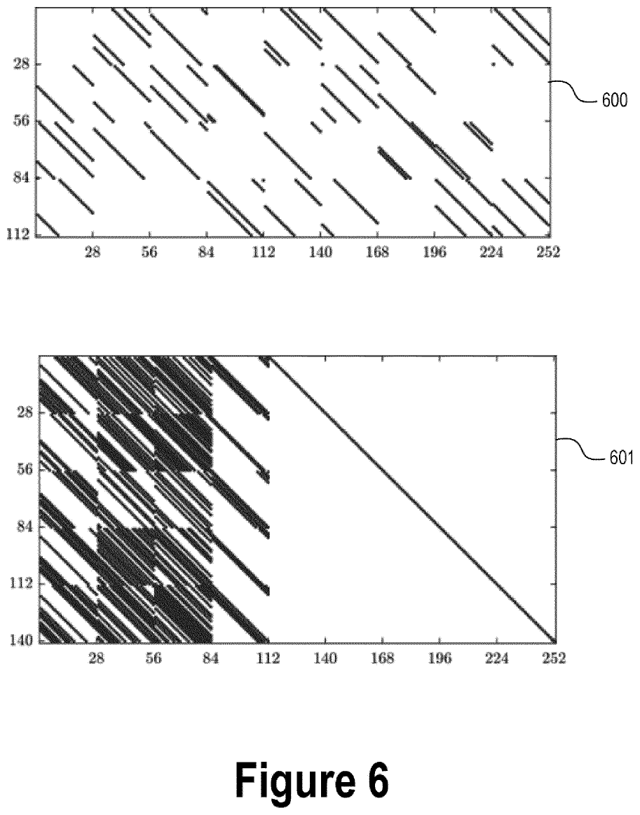

FIG. 6 is a schematic graphic representation of the quasi-cyclic check matrix H and the quasi-cyclic generator matrix G, both for geometry Q(5,3), i.e., geometry Q(5,q) with q=3.

The block size is b=28 and ω is a primitive element of F₃_{⁶}.

For q=3, the following is computed:

X={ω²,ω⁴⁷⁴,ω⁶¹⁶,ω⁵⁷²}.

A={ω²,ω¹⁰,ω⁴,ω⁶⁷¹,ω⁴⁷⁴,ω⁶¹⁶,ω⁴⁵⁴,ω⁴⁰¹,ω⁴⁷⁵}.

The matrix H is fully described by H^{rep}, a (q+1)×q² matrix whose rows are indexed by elements of X and whose columns are indexed by elements of A. For x∈X and a∈A, the H_{a,x} entry of H^{rep} is a subset H_{a,x}^{rep} of {0, . . . , b−1} whose elements indicate a 1-coordinate of the first row of the circulant matrix occupying the corresponding position in the quasi-cyclic matrix H.

Let α=ω^{q}^{³}⁻¹, so that a is a primitive b-th root of unity in F= [symbol] _{q}_{⁶}.

The quasi-cyclic representation of the elliptic quadrangle is given by r∈H_{x,a}^{rep} if and only if

$${a ( {α}^{r} x )}^{q + 1} - {α}^{r} x + {a}^{{q}^{2}} = 0 ,$$

where r runs from 0 to b−1.

Returning to the case q=3, the quasi-cyclic representation of the elliptic quadrangle Q(5,3) is given by a 4×9 matrix H^{rep}. To compute the (1,1) entry in H^{rep} (i.e. the top-left entry in the matrix), those r∈{0, . . . , 27} are determined for which

$${a ( {α}^{r} x )}^{4} - {α}^{r} x + {a}^{9} = 0 ,$$

where a=ω², x=ω² and α=ω²⁶. It turns out that no such r exists, so H_{x,a}^{rep} is the empty set in this case. To determine the next entry in the matrix (i.e the (1,2) entry), those r∈{0, . . . , 27} are computed for which

$${a ( {α}^{r} x )}^{4} - {α}^{r} x + {a}^{9} = 0 ,$$

where a=ω¹⁰, x=ω² and α=ω²⁶. It turns out that both r=9 and r=15 work, so the subset is {9,15}. Continuing in this way, it is determined that the matrix H^{rep} is

$$( \begin{matrix} & 9 , 15 & 25 & & 8 , 12 & 1 & 16 & & 1 , 10 \\ 18 & 10 & 0 , 18 & 3 , 4 & & 7 , 19 & 14 & & \\ 1 , 9 & 25 & 24 & & 23 & & 14 , 16 & 14 , 17 & \\ 11 & & & 22 , 27 & 15 & 6 & & 0 , 15 & 5 , 16\end{matrix} ) .$$

To construct the quasi-cyclic check matrix H from H^{rep}, we substitute each empty set with a b×b matrix of zeros and each subset {r} by an identity matrix cyclically shifted to the right by r bits. If there is more than one entry in the subset then we superimpose these cyclic shifts. Thus, the quasi-cyclic check matrix H for Q(5,3) (i.e., with q=3) is the one shown in FIG. 6 indicated with number reference 600.

Gaussian elimination is applied directly on H^{rep}, to obtain a quasi-cyclic generator matrix in standard form for the code. As mentioned before, it is not always the case that there exists a generator matrix in standard quasi-cyclic form, so it is provided a generator matrix G for a large subcode C′ for which there is a generator matrix in standard quasi-cyclic form. Let k be the dimension of the code C′. The matrix G can be described by a (k/b)×((n−k)/b) matrix P^{repp}, where the (i,j) entry of P^{rep} is Pᵢⱼ, a vector of {0,1}^{b}. It is provided a matrix P^{rep}, whose entries are the first row of a b×b circulant matrix. Recall that, replacing each first row with the full circulant b×b matrix, it is obtained a matrix P, where G=(P|id) is a generator matrix for the implementable code C′.

In the example for q=3 the matrix P^{rep} is the following matrix:

| | | | | | | | | | | | | | | | | | | | | | | | | | | | |
|---|---|---|---|---|---|---|---|---|---|---|---|---|---|---|---|---|---|---|---|---|---|---|---|---|---|---|---|
| (((0 | 0 | 0 | 0 | 0 | 0 | 0 | 1 | 1 | 0 | 1 | 1 | 0 | 1 | 0 | 1 | 1 | 1 | 0 | 0 | 0 | 0 | 0 | 0 | 1 | 0 | 0 | 0) |
| (1 | 0 | 0 | 1 | 0 | 0 | 1 | 0 | 0 | 1 | 1 | 1 | 0 | 1 | 0 | 1 | 0 | 0 | 1 | 0 | 1 | 1 | 1 | 0 | 0 | 0 | 1 | 0) |
| (1 | 1 | 1 | 0 | 1 | 0 | 1 | 0 | 0 | 1 | 0 | 0 | 0 | 0 | 1 | 0 | 0 | 1 | 0 | 0 | 1 | 1 | 1 | 1 | 0 | 0 | 1 | 1) |
| (1 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 1 | 1 | 0 | 1 | 1)) |
| ((0 | 0 | 0 | 0 | 0 | 1 | 0 | 0 | 0 | 1 | 1 | 0 | 0 | 0 | 1 | 1 | 0 | 0 | 0 | 0 | 0 | 0 | 0 | 0 | 0 | 0 | 0 | 0) |
| (1 | 0 | 1 | 0 | 1 | 0 | 0 | 1 | 0 | 0 | 0 | 0 | 0 | 1 | 1 | 1 | 1 | 1 | 1 | 1 | 0 | 0 | 0 | 0 | 0 | 1 | 0 | 1) |
| (1 | 0 | 1 | 1 | 1 | 1 | 1 | 0 | 0 | 1 | 1 | 0 | 1 | 1 | 1 | 1 | 1 | 1 | 1 | 0 | 1 | 0 | 0 | 0 | 0 | 1 | 1 | 1) |
| (0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 1 | 1 | 0)) |
| ((0 | 0 | 0 | 0 | 0 | 0 | 1 | 0 | 1 | 1 | 0 | 0 | 1 | 1 | 1 | 0 | 1 | 1 | 0 | 0 | 0 | 0 | 0 | 0 | 0 | 0 | 0 | 0) |
| (0 | 1 | 1 | 0 | 0 | 0 | 0 | 1 | 1 | 0 | 0 | 1 | 0 | 1 | 0 | 0 | 0 | 0 | 0 | 0 | 0 | 0 | 0 | 0 | 1 | 0 | 0 | 0) |
| (0 | 1 | 0 | 0 | 0 | 0 | 1 | 0 | 0 | 1 | 0 | 1 | 0 | 0 | 0 | 0 | 0 | 0 | 0 | 0 | 0 | 1 | 0 | 0 | 1 | 0 | 0 | 1) |
| (1 | 0 | 0 | 0 | 0 | 0 | 0 | 0 | 0 | 0 | 0 | 0 | 0 | 0 | 0 | 0 | 0 | 0 | 0 | 0 | 0 | 0 | 1 | 0 | 1 | 1 | 0 | 1)) |
| ((0 | 0 | 0 | 0 | 0 | 0 | 0 | 1 | 1 | 1 | 0 | 1 | 1 | 1 | 1 | 0 | 0 | 0 | 0 | 0 | 0 | 0 | 0 | 0 | 1 | 0 | 0 | 0) |
| (1 | 0 | 0 | 1 | 1 | 0 | 0 | 1 | 0 | 1 | 1 | 1 | 0 | 1 | 1 | 0 | 0 | 1 | 1 | 0 | 1 | 0 | 1 | 1 | 1 | 0 | 1 | 0) |
| (1 | 1 | 0 | 0 | 1 | 0 | 0 | 0 | 0 | 0 | 0 | 1 | 1 | 1 | 0 | 0 | 1 | 1 | 0 | 0 | 0 | 1 | 0 | 0 | 1 | 1 | 1 | 0) |
| (0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 1 | 1 | 1 | 0 | 0)) |
| ((0 | 0 | 0 | 0 | 0 | 0 | 1 | 1 | 1 | 1 | 1 | 0 | 0 | 1 | 1 | 1 | 0 | 1 | 0 | 0 | 0 | 0 | 0 | 1 | 0 | 0 | 0 | 0) |
| (1 | 0 | 1 | 1 | 0 | 0 | 1 | 1 | 1 | 1 | 1 | 1 | 0 | 0 | 1 | 0 | 0 | 0 | 1 | 1 | 0 | 1 | 0 | 0 | 0 | 0 | 0 | 1) |
| (1 | 1 | 1 | 1 | 0 | 0 | 1 | 1 | 0 | 0 | 1 | 0 | 1 | 1 | 0 | 0 | 0 | 1 | 0 | 0 | 1 | 1 | 1 | 1 | 1 | 1 | 1 | 1) |
| (1 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 1 | 1 | 1 | 1 | 0))). |

Thus, the quasi-cyclic generator matrix G for Q(5,3) (i.e., with q=3) is the one shown in FIG. 6 indicated with number reference 601.

The block size b is 28, so the check matrix H is a 112×252 matrix and the generator matrix G of the code C′ is a 140×252 matrix. This [252,140] code C′ is the code whose parameters appear in the first row in Table 3. It has been constructed from the quasi-cyclic representation of the elliptic quadric quadrangle Q(5,3). Observe that is fully described by the matrices H^{rep} and P^{rep}.

It is understood that numerous modifications and variations could be made thereto by those skilled in the art without departing from the spirit and scope of the disclosure. For example, that labelling the rows of a parity check matrix H with r-dimensional subspaces and the columns by s-dimensional subspaces of a certain geometry, where a 1 entry is given by containment, one may deduce equations which if chosen carefully enough a quasi-cyclic matrix may be obtained. More obvious modifications may be made like removing columns blocks or row blocks. It is therefore to be understood that within the scope of the claims, the disclosure may be practiced otherwise than as specifically described herein.

1. A digital communication coding method, comprising:
generating families of quasi-cyclic low-density parity-check, LDPC, codes each represented by a single equation, said single equation being derived from a geometry whose nature implies good error correcting properties for each of the LDPC codes, and the equation allowing quasi-cyclic parity check matrices to be constructed for geometric LDPC codes of exceedingly long length, up to and exceeding four hundred thousand bits, the construction of such check matrices being not possible by any other known method; wherein
the LDPC codes have different lengths and different rates and the families of LDPC codes are generated with a guarantee of minimum distance; and wherein
the geometric and quasi-cyclic properties of the LDPC codes allow low complexity decoding with very low frame error rates.

2. The digital communication coding method according to claim 1, further comprising puncturing at least one check bit from one or more of the LDPC codes.

3. The digital communication coding method according to claim 1, wherein the LDPC codes have length equal to or above 20000 bits.

4. A digital communication encoding method, comprising:
the digital communication coding method according to claim 1 to generate LDPC codes; and
encoding data by adding redundancy bits based on the generated LDPC codes.

5. A digital communication decoding method, comprising:
the digital communication coding method according to claim 1 to generate LDPC codes; and
decoding data by correcting errors introduced by a noisy communication channel, said correction based on the generated LDPC codes.

6. A method of producing a digital communication coding hardware, comprising:
the digital communication coding method according to claim 1 to generate LDPC codes; and
producing the digital communication coding hardware based on the generated LDPC codes.

7. The digital communication coding hardware produced by the method according to claim 6 of producing the digital communication coding hardware.

8. A digital communication coding system, comprising:
a system module configured to generate families of quasi-cyclic low-density parity-check, LDPC, codes each represented by a single equation, said single equation being derived from a geometry whose nature implies good error correcting properties for each of the LDPC codes, and the equation allowing quasi-cyclic parity check matrices to be constructed for geometric LDPC codes of exceedingly long length, up to and exceeding four hundred thousand bits, the construction of such check matrices being not possible by any other known method; wherein
the LDPC codes have different lengths and different rates and the families of LDPC codes are generated with a guarantee of minimum distance; and wherein
the geometric and quasi-cyclic properties of the LDPC codes allow low complexity decoding with very low frame error rates.

9. A computer program product comprising program instructions for causing a computer or computing system to perform a digital communication coding method comprising:
generating families of quasi-cyclic low-density parity-check, LDPC, codes each represented by a single equation, said single equation being derived from a geometry whose nature implies good error correcting properties for each of the LDPC codes, and the equation allowing quasi-cyclic parity check matrices to be constructed for geometric LDPC codes of exceedingly long length, up to and exceeding four hundred thousand bits, the construction of such check matrices being not possible by any other known method; wherein
the LDPC codes have different lengths and different rates and the families of LDPC codes are generated with a guarantee of minimum distance; and wherein
the geometric and quasi-cyclic properties of the LDPC codes allow low complexity decoding with very low frame error rates.

10. The computer program product according to claim 9 embodied on a storage medium.

11. The computer program product according to claim 9 carried on a carrier signal.

12. A computing system comprising a memory and a processor, embodying instructions stored in the memory and executable by the processor, and the instructions comprising functionality or functionalities to execute the digital communication coding method according to claim 1.

13. A digital communication transmitter system, comprising:
an encoding module configured to encode data based on LDPC codes generated by the digital communication coding method according to claim 1, or by a digital communication coding hardware based on LDPC codes generated by the digital communication coding method, or by a computer program comprising program instructions for causing a computer or computing system to perform the digital communication coding method, or by a computing system comprising a memory and a processor, embodying instructions stored in the memory and executable by the processor, and the instructions comprising functionality or functionalities to execute a digital communication coding method, and
a transmission module configured to transmit the encoded data.

14. A digital communication receiver system, comprising:
a receiving module configured to receive data; and
a decoding module configured to decode the received data based on LDPC codes generated by the digital communication coding method according to claim 1, or by a digital communication coding hardware based on LDPC codes generated by the digital communication coding method, or by a computer program comprising program instructions for causing a computer or computing system to perform the digital communication coding method, or by a computing system comprising a memory and a processor, embodying instructions stored in the memory and executable by the processor, and the instructions comprising functionality or functionalities to execute the digital communication coding method.
